(19) United States
(12) Patent Application Publication
(10) Pub. No.: US 2021/0288195 A1
(43) Pub. Date: Sep. 16, 2021

(54) Colloidal Quantum Dot (CQD) Photodetectors and Related Devices

(71) Applicant: SWIR Vision Systems Inc., Durham, NC (US)

(72) Inventors: Ethan Klem, Chapel Hill, NC (US); Sean Hinds, Ottawa (CA); Christopher Gregory, Chapel Hill, NC (US); Jeffery Allan Hilton, Durham, NC (US)

(21) Appl. No.: 17/199,971

(22) Filed: Mar. 12, 2021

Related U.S. Application Data
(60) Provisional application No. 62/988,994, filed on Mar. 13, 2020.

(51) Int. Cl. H01L 31/0352; H01L 31/101; H01L 27/30; H01L 31/0216

(52) U.S. Cl. CPC H01L 31/035218; H01L 31/02164; H01L 27/307; H01L 31/1013

(57) ABSTRACT

A colloidal quantum dot (CQD) photodetector is provided including an optical blocking shield and a CQD photodetector element on the optical blocking shield. The optical blocking shield is integrated with the CQD photodetector element to provide an integrated structure and the integrated structure is provided on a wafer. The CQD photodetector detects light with sensitivity from about 250 nm to about 5000 nm. The CQD photodetector may be included as part of high resolution applications as well as global shutters for these applications.

### CLAIM OF PRIORITY

The present application claims priority to U.S. Provisional Application No. 62/988,944, filed on Mar. 13, 2020, entitled Global Shutter Optical Interface Blocker for Quantum Dot Optical Sensors, the content of which is hereby incorporated herein by reference as if set forth in its entirety.

### FIELD

The present inventive concept relates generally to photodetectors for use in global shutter sensor arrays, more particularly, to photodetectors formed by quantum dots for use in global shutter sensor arrays.

### BACKGROUND

Cameras generally have a “shutter” that allows light to be collected for a determined period of time, exposing photographic film or a light-sensitive electronic sensor to light in order to capture a permanent image of a scene. There are different types of shutters. A “rolling shutter” is used when an image is scanned sequentially, from one side of the sensor (usually the top) to the other, line by line. A “global shutter,” on the other hand, is used when entire area of the image is scanned and captured simultaneously.

Global shutter technology is well suited for capturing images of moving objects. In particular, a global shutter exposes all lines of an image at the same time, in essence freezing the moving object in place. This reduces the likelihood, or possibly prevents, distortions, which makes global shutter technology a good choice for applications with moving objects and rapid movement sequences, such as identification, hyper spectral imaging, LIDAR, eye-safe and invisible scene illumination, mobile cameras, vehicle imaging assistance systems and the like.

Conventional global shutter light sensor arrays generally require the inclusion of a pixel-level memory element, or storage node, in addition to the light sensing element. In global shutter silicon (Si) complementary metal-oxide-semiconductor (CMOS) image sensors, for example, individual pixels typically contain both a Si photodiode, and a sample and hold circuit that serves as the memory element. The co-location of the light sensing element and the memory element within a pixel's area imposes practical restrictions on the minimum pixel pitch that can be achieved in Si CMOS global shutter sensors. Thus, improved methods and devices are desired for fabricating small pixel pitch global shutter sensor arrays.

A photodetector may be based on a junction formed by a pair of two different types of semiconductors, for example, an n-type and a p-type material, or an electron acceptor and an electron donor material). When a photon's energy is higher than the band gap value of the semiconductor, the photon can be absorbed in the semiconductor and the photon's energy excites a negative charge (electron) and a positive charge (hole). For the excited electron-hole pair to be successfully utilized in an external electrical circuit, the electron and the hole must first be separated before being collected at and extracted by respective opposing electrodes. This process is called charge separation and is required for photoconductive and photovoltaic effects to occur. If the charges do not separate they can recombine and, thus, may not contribute to the electrical response generated by the device.

In photodetector devices, a key figure of merit is quantum efficiency, which includes both external quantum efficiency (EQE) and internal quantum efficiency (IQE). EQE corresponds to the percentage of total incident photons that are converted to electrical current, and IQE corresponds to the percentage of total absorbed photons that are converted to electrical current. Another performance-related criterion is the signal-to-noise (S/N) ratio of the device, which generally may be maximized by maximizing the EQE and minimizing the dark current. As used herein, “dark current” refers to the residual electric current flowing in a photoelectric device when there is no incident illumination. In physics and in electronic engineering, dark current is the relatively small electric current that flows through photosensitive devices such as a photomultiplier tube, photodiode, or charge-coupled device even when no photons are entering the device. The dark current generally consists of the charges generated in the detector when no outside radiation is entering the detector. It can be referred to as reverse bias leakage current in non-optical devices and is present in all diodes. Physically, one source dark current is due to the thermal generation of electrons and holes within the depletion region of the device.

In addition, charge carrier mobility within the constituent layers is a key material property that affects the performance of the device. Charge carrier mobility describes the velocity of a charge carrier in the presence of an electric field. A larger value of mobility means that charge carriers move more freely and can be extracted from the device more efficiently. This results in higher device performance as compared devices with lower charge carrier mobility. A related property is exciton diffusion length, which describes the average distance that an exciton (a bound electron-hole pair) will travel before the charge carriers recombine. In a photodetector or related device where excitons play a significant role, a larger value means that there is a higher probability that photogenerated excitons will reach a charge separation region prior to recombination, and also leads to a higher device performance as compared to a photodetector device with a lower exciton diffusion length. While mobility and exciton diffusion are separate properties, their values are affected by similar material attributes. For example, defects, charge trapping sites, and grain boundaries all inhibit carrier transport and result in lower mobility as well as lower exciton diffusion length. While enhanced mobility is discussed throughout this document, it is understood that similar results are obtained for enhanced exciton diffusion length.

Conventionally, photodetector devices and other optoelectronic devices have utilized bulk and thin-film inorganic semiconductor materials to provide p-n junctions for separating electrons and holes in response to absorption of photons. In particular, electronic junctions are typically formed by various combinations of intrinsic, p-type doped and n-type doped silicon. The fabrication techniques for such inorganic semiconductors are well-known as they are derived from many years of experience and expertise in microelectronics. Detectors composed of silicon-based p-n junctions are relatively inexpensive when the devices are small, but costs scale approximately with detector area. Moreover, the bandgap of silicon (Si) limits the range of infrared (IR) sensitivity to about 1.1 μm. Because silicon has an indirect bandgap and is a relatively inefficient absorber of photons, there is a wide distribution of absorption lengths as a function of wavelength, making it difficult to produce detectors that are simultaneously efficient in the ultraviolet (UV) and the IR. Group III-V materials such as indium-gallium-arsenide [InₓGa_{y}As (x+y=1, 0≤x≤1, 0≤y≤1)], germanium (Ge) and silicon-germanium (SiGe), have been utilized to extend detection further into the IR but suffer from more expensive and complicated fabrication issues. Other inorganic materials such as AlₓGa_{y}In_{z}N (x+y+z=1, 0≤x≤1, 0≤y≤1, 0≤z≤1), silicon carbide (SiC), and titanium oxide (TiO₂) have been used for more efficient UV detection, but also suffer from complex fabrication and cost issues.

As used herein, “bandgap” refers to the difference in energy between the valence band and the conduction band of a solid material, such as an insulator or semiconductor, that consists of the range of energy values forbidden to electrons in the material.

More recently, optoelectronic devices formed from organic materials, for example, polymers and small molecules, are being investigated, but have enjoyed limited success as photodetectors. The active region in these devices is based on a heterojunction formed by an organic electron donor layer and an organic electron acceptor layer. A photon absorbed in the active region excites an exciton, an electron-hole pair in a bound state that can be transported as a quasi-particle. The photogenerated exciton becomes separated (dissociated or “ionized”) when it diffuses to the heterojunction interface. Similar to inorganic photovoltaic (PV) and photodetector devices, it is desirable to separate as many of the photogenerated excitons as possible and collect them at the respective electrodes before they recombine. It can therefore be advantageous to include layers in the device structure that help confine excitons to charge separation regions. These layers may also serve to help transport one type of charge carrier to one electrode, while blocking other charge carriers, thereby improving the efficiency of charge carrier extraction. While many types of organic semiconductor layers can be fabricated at relatively low-cost, most organic semiconductor layers are not sufficiently sensitive to IR photons, which is disadvantageous in IR imaging applications. Moreover, organic materials are often prone to degradation by UV radiation or heat.

Even more recently, quantum dots (QDs), or nanocrystals, have been investigated for use in optoelectronic devices because various species exhibit IR sensitivity and their optoelectronic properties, for example, bandgaps, are tunable by controlling their size. Thus far, QDs have been employed in prototype optoelectronic devices mostly as individual layers to perform a specific function such as visible or IR emission, visible or IR absorption, or red-shifting. Moreover, optoelectronic devices incorporating QDs have typically exhibited low carrier mobility and short diffusion length.

A photodetector may form the basis of an imaging device such as, for example, a digital camera capable of producing still photographs and/or video streams from an observed scene. The imaging device in such applications typically includes a light-sensitive focal plane array (FPA) composed of many photodetectors and coupled to imaging electronics, for example, read-out chips. The photodetector of a typical digital camera is based on silicon technology.

Silicon digital cameras have offered outstanding performance at low cost by leveraging Moore's Law of silicon technology improvement. The use of silicon alone as the light-absorbing material in such cameras, however, limits the efficient operation of these cameras in the infrared spectrum. Silicon is therefore not useful in the portion of the electromagnetic spectrum known as the short-wavelength infrared (SWIR), which spans wavelengths from about 1.0 to 2.5 μm. The SWIR band is of interest for night vision applications where imaging using night glow and reflected light offers advantages over the longer thermal infrared wavelengths. Similarly, the typical IR-sensitive imaging device composed of, for example, InGaAs, InSb, or HgCdTe is not capable of also performing imaging tasks in the visible and UV ranges. Hence the requirement in many imaging systems for both daytime and nighttime imaging has resulted in the use of multi-component systems containing silicon-based imagers and separate specialized IR imagers. The necessity of utilizing multiple technologies increases costs and complexity. Moreover, SWIR imaging is useful, for example, in military surveillance and commercial security surveillance applications and is considered to have technological advantages over mid-wavelength infrared (MWIR) and long-wavelength infrared (LWIR) imaging, but thus far has been limited to use in high-performance military applications due to the high costs associated with traditional design and fabrication approaches. Additionally, while FPAs exhibiting good sensitivity to incident IR radiation have been developed based on a variety of crystalline semiconductors, such FPAs conventionally have been required to be fabricated separately from the read-out chips. Conventionally, after separately fabricating an FPA and a read-out chip, these two components are subsequently bonded together by means of alignment tools and indium solder bumps, or other flip-chip or hybridization techniques. This also adds to fabrication complexity and expense.

There is an ongoing need for photodetector devices with improved material properties and performance-related parameters such as more efficient charge separation, greater charge carrier mobility, longer diffusion lengths, higher quantum efficiencies, and sensitivity tunable to a desired range of electromagnetic spectra. There is also a need for lower cost, more reliable and more facile methods for fabricating such photodetector devices, as well as improved integration of the sensing elements with the signal processing electronics, improved scalability for large-area arrays, and applicability to curved, flexible or foldable substrates. There is also a need for photodetector devices that exhibit a sensitivity spanning a broad spectral range, such as both visible and IR or UV, visible and IR, to enable simultaneous detection in these ranges by a single photodetector device.

### SUMMARY

Some embodiments of the present inventive concept provide a colloidal quantum dot (CQD) photodetector including an optical blocking shield and a CQD photodetector element on the optical blocking shield. The optical blocking shield is integrated with the CQD photodetector element to provide an integrated structure and the integrated structure is provided on a wafer. The CQD photodetector detects light with sensitivity from about 250 nm to about 5000 nm.

In further embodiments of the present inventive concept the optical blocking shield may be an optically opaque material. The optically opaque material may be one or more layers of a metal material. The optical blocking shield may have a thickness of from about 10 nm to about 3000 nm. The metal material may include one or more of Au, Ag, W, Cu, Ti, Cr, Ni, Ge and Ta.

In still further embodiments, the optical blocking shield may include a dielectric material.

In some embodiments, the presence of the optical blocking shield may substantially prevent stray photons from entering silicon circuitry in the wafer under the optical blocking shield.

In further embodiments, the wafer may include a silicon wafer and the CQD photodetector may be positioned directly on a surface of the silicon wafer.

In still further embodiments, the CQD photodetector may be positioned in a high resolution light sensing application.

In some embodiments, the CQD photodetector may be positioned in multispectral device that produces images from one or more of incident ultraviolet (UV) electromagnetic radiation, visible electromagnetic radiation and/or infrared electromagnetic radiation.

In further embodiments, the CQD photodetector may be part of a global shutter in an imaging device.

In still further embodiments, the wafer may be a single wafer.

In some embodiments, the single wafer may include circuitry for an amplifier.

In further embodiments, the CQD photodetector may be used in multi-pixel light sensing arrays.

Still further embodiments of the present inventive concept provide a global shutter for use with an imaging device. The global shutter includes a colloidal quantum dot (CQD) photodetector. The CQD photodetector includes an optical blocking shield and a CQD photodetector element on the optical blocking shield. The optical blocking shield is integrated with the CQD photodetector element to provide an integrated structure and the integrated structure is provided on a wafer. The CQD photodetector detects light with sensitivity from about 250 nm to about 5000 nm.

In some embodiments, the global shutter may have an improved shutter rejection ratio (SRR) relative to conventional global shutters.

In further embodiments, the global shutter may include global shutter sensing array provided on a single wafer.

In still further embodiments, presence of the optical blocking shield in the CQD photodetector may prevent photons from entering a region of the wafer including silicon circuitry that contains an amplifier, charge storage, and memory elements used to implement global shutter operation.

In some embodiments, presence of the optical blocking shield may decreases noise in a global shutter sensor by reducing impact of parasitic stray light on associated image data.

In further embodiments, the imaging device may be a high resolution light sensing application.

In still further embodiments, the optical blocking shield may include one or more layers of at least one of an optically opaque material, a metal material and a dielectric material. The optical blocking shield may have a thickness of from about 10 nm to about 3000 nm.

### BRIEF DESCRIPTION OF THE DRAWINGS

FIG. 1 is a cross section of a photodetector device including an optical blocking layer in accordance with some embodiments of the present inventive concept.

FIG. 2 is a simplified cross section of a CQD photodetector having an integrated optical blocking shield on a wafer (existing sensor chip) in accordance with some embodiments of the present inventive concept.

FIG. 3 is an optical microscope image of an array of optical blocking elements formed on the surface of an amplifier integrated circuit in accordance with some embodiments of the present inventive concept.

FIG. 4 is an image illustrating a portion of a device cross section and surface features in accordance with some embodiments of the present inventive concept.

FIG. 5 is a cross-section illustrating a photodetector global shutter pixel that incorporates and an optical blocking element and a quantum dot photodiode structure in accordance with some embodiments of the present inventive concept.

FIG. 6 is a cross section illustrating a photodetector pixel sitting on top of a metal optical blocking element on top of an electrical contact formed in the silicon wafer to provide a path for photocurrent to be transferred into the amplifier IC in accordance with some embodiments of the present inventive concept.

FIG. 7 is a block diagram illustrating a CQD photodetector positioned in an imaging device in accordance with some embodiments of the present inventive concept.

### DETAILED DESCRIPTION

The present inventive concept will be described more fully hereinafter with reference to the accompanying figures, in which embodiments of the inventive concept are shown. This inventive concept may, however, be embodied in many alternate forms and should not be construed as limited to the embodiments set forth herein.

Accordingly, while the inventive concept is susceptible to various modifications and alternative forms, specific embodiments thereof are shown by way of example in the drawings and will herein be described in detail. It should be understood, however, that there is no intent to limit the inventive concept to the particular forms disclosed, but on the contrary, the inventive concept is to cover all modifications, equivalents, and alternatives falling within the spirit and scope of the inventive concept as defined by the claims. Like numbers refer to like elements throughout the description of the figures.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof. Moreover, when an element is referred to as being “responsive” or “connected” to another element, it can be directly responsive or connected to the other element, or intervening elements may be present. In contrast, when an element is referred to as being “directly responsive” or “directly connected” to another element, there are no intervening elements present. As used herein the term “and/or” includes any and all combinations of one or more of the associated listed items and may be abbreviated as “/”.

Unless otherwise defined, all terms (including technical and scientific terms) used herein have the same meaning as commonly understood by one of ordinary skill in the art to which this inventive concept belongs. It will be further understood that terms used herein should be interpreted as having a meaning that is consistent with their meaning in the context of this specification and the relevant art and will not be interpreted in an idealized or overly formal sense unless expressly so defined herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure. Although some of the diagrams include arrows on communication paths to show a primary direction of communication, it is to be understood that communication may occur in the opposite direction to the depicted arrows.

As used herein, the term “optoelectronic device” generally refers to any device that acts as an optical-to-electrical transducer or an electrical-to-optical transducer. Accordingly, the term “optoelectronic device” may refer to, for example, a photovoltaic (PV) device (e.g., a solar cell), a photodetector, a thermovoltaic cell, or electroluminescent (EL) devices such as light-emitting diodes (LEDs) and laser diodes (LDs). In a general sense, EL devices operate in the reverse of PV and photodetector devices. Electrons and holes are injected into the semiconductor region from the respective electrodes under the influence of an applied bias voltage. One of the semiconductor layers is selected for its light-emitting properties rather than light-absorbing properties. Radiative recombination of the injected electrons and holes causes the light emission in this layer. Many of the same types of materials employed in PV and photodetector devices may likewise be employed in EL devices, although layer thicknesses and other parameters must be adapted to achieve the different goal of the EL device.

As used herein, the term “quantum dot” or “QD” refers to a semiconductor material in which charge carriers are confined in all three spatial dimensions, as distinguished from quantum wires (quantum confinement in only two dimensions), quantum wells (quantum confinement in only one dimension), and bulk semiconductors (unconfined). Also, many optical, electrical and chemical properties of the quantum dot may be strongly dependent on its size, and hence such properties may be modified or tuned by controlling its size. A quantum dot may generally be characterized as a particle, the shape of which may be spheroidal, ellipsoidal, or other shape. The “size” of the quantum dot may refer to a dimension characteristic of its shape or an approximation of its shape, and thus may be a diameter, a major axis, a predominant length, etc. The size of a quantum dot is on the order of nanometers, i.e., generally ranging from 1.0-1000 nm, but more typically ranging from 1.0-100 nm, 1.0-20 nm or 1-10 nm. In a plurality or ensemble of quantum dots, the quantum dots may be characterized as having an average size. The size distribution of a plurality of quantum dots may or may not be monodisperse. The quantum dot may have a core-shell configuration, in which the core and the surrounding shell may have distinct compositions. The quantum dot may also include ligands attached to its outer surface or may be functionalized with other chemical moieties for a specific purpose.

Plasma synthesis has evolved to be one of the most popular gas-phase approaches for the production of quantum dots, especially those with covalent bonds. For example, silicon (Si) and germanium (Ge) quantum dots have been synthesized by using nonthermal plasma. The size, shape, surface and composition of quantum dots can all be controlled in nonthermal plasma. Doping that seems quite challenging for quantum dots has also been realized in plasma synthesis. Quantum dots synthesized by plasma are usually in the form of powder, for which surface modification may be carried out. This can lead to excellent dispersion of quantum dots in either organic solvents or water, i.e., colloidal quantum dots (CQD). Quantum dots in accordance with embodiments discussed herein can be produced by any method known and, therefore, production methods are not limited to plasma synthesis. For example, quantum dots may be fabricated using organometallic synthesis without departing from the scope of the present inventive concept. Embodiments of the present inventive concept use CQD films as discussed below.

For purposes of the present disclosure, the spectral ranges or bands of electromagnetic radiation are generally taken as follows, with the understanding that adjacent spectral ranges or bands may be considered to overlap with each other to some degree: ultra-violate (UV) radiation may be considered as having a photon wavelength falling within the range of about 10-400 nm, although in practical applications (above vacuum) the range is about 200-400 nm. Visible radiation may be considered as falling within the range of about 380-760 nm. Infrared (IR) radiation may be considered as falling within the range of about 750-100,000 nm. IR radiation may also be considered in terms of sub-ranges, examples of which are as follows. Near infrared radiation (NIR) may be considered as falling within the range of about 750-1000 nm. Short wave infrared (SWIR) radiation may be considered as falling within the range of about 1,000-3,000 nm. Medium wave infrared (MWIR) radiation may be considered as falling within the range of about 3,000-5,000 nm. Long range infrared (LWIR) radiation may be considered as falling within the range of about 8,000-12,000 nm.

As discussed below, quantum dot photodiode (QDP) technology is implemented to provide low-cost nanotechnology-enabled photodetectors. In some implementations, the photodetectors may be configured to efficiently detect light with sensitivity spanning a spectral region ranging from about 250-2400 nm. Thus, the photodetectors may be configured as a multispectral device capable of producing images from incident ultraviolet (UV), visible and/or infrared (IR) electromagnetic radiation. In some implementations, the spectral range of sensitivity may extend down to X-ray energies and/or up to IR wavelengths longer than 2400 nm. The photodetectors as taught herein are cost effective, scalable to large-area arrays, and applicable to flexible substrates.

Global snapshot shutter technology is well suited for capturing images of moving objects. Use of this type of shutter reduces the likelihood, or possibly prevents, distortions, which makes global shutter technology a good choice for applications with moving objects and rapid movement sequences, like facial identification, hyper spectral imaging, LIDAR, eye-safe and invisible scene illumination, mobile cameras, vehicle imaging assistance systems and the like. Available global shutter sensors that incorporate a CQD film may not provide sufficient performance. Accordingly, some embodiments of the present inventive concept provide a photodetector incorporating a CQD film with an additional optical blocking shield/layer. The addition of the optical blocking shield may provide a higher shutter rejection ratio, which may in turn provide an improved global shutter performance as discussed further below.

As used herein, “shutter rejection ratio” (SRR) refers to the ratio of the photo-generated signal captured during a single image exposure time, to the change in that signal that occurs during the read-out of the image. In CMOS image sensors utilizing silicon photodiodes for light detection, the SRR is commonly defined as discussed in, for example, Ultra High Light Shutter Rejection Ratio Snapshot Pixel Image Sensor ASIC for Pattern Recognition by Yang et. al, the contents of which are hereby incorporated herein by reference. In CMOS global shutter image sensors, poor shutter rejection ratios (SRRs) are typically the result of photo-generated charge carriers in the silicon substrate leaking into the charge storage node during the time it takes for the image sensor to transfer the image data from the charge storage node to the image sensor outputs.

Embodiments of the present inventive concept are discussed herein with respect to SWIR-sensitive photodetector which incorporates a CQD film in addition to an optical blocking shield. It will be understood that embodiments of the present inventive concept are not limited to configurations discussed herein and that the optical blocking shield can be used in any device type where it would be deemed useful without departing from the scope of the present inventive concept.

As discussed above, photodetectors fabricated using CQDs may be used to build multi-pixel light sensing arrays. Advantages of CQD-based photodetectors include the ability to be tuned to respond to a wide range of wavelengths of light, spanning the ultraviolet to the infrared spectral region. For example, CQD photodiodes designed to be sensitive to near infrared (NIR) light having wavelengths between 800 to 1000 nm and SWIR light having wavelengths in between 1000 to 2500 nm can be used to build NIR and SWIR-based two-dimensional and three-dimensional imaging and depth sensing systems. It will be understood that the wavelength ranges for NIR and SWIR may vary based on the source of the information and, therefore, embodiments of the present inventive concept are not limited to the ranges set out herein. Furthermore, photodetectors fabricated using CQDs may also be fabricated directly on the surface of a silicon integrated circuit and be formed into small pixels. The combination of direct-on-silicon fabrication, i.e., monolithic integration, and small pixel pitch, makes CQD photodetectors particularly well suited to low-cost, high resolution light-sensing applications, such as digital cameras.

As discussed above, there are different types of shutters, for example, rolling shutters and global shutters. Photosensor arrays can be fabricated with either a rolling shutter architecture or a global shutter architecture. Generally, a global shutter architecture is better suited to applications that require fast frame rates and synchronized data capture of all pixels in an array. This follows as global shutters architectures are configured to scan an entire area of the image simultaneously. Applications that lend themselves to global shutter architecture include structured light three-dimensional depth sensing systems. The implementation of a global shutter architecture generally requires additional circuitry, compared to a rolling shutter architecture, commonly referred to as a storage node to be incorporated into the readout circuit. This storage node circuitry serves to store collected photo-charges and to synchronize the pixel level snap-shot reconstruction of a two-dimensional focal plane array.

In a conventional complementary metal-oxide semiconductor (CMOS) image sensor circuit each pixel contains both the photodiode element and pixel-level circuitry including, for example, amplifier circuitry and charge storage circuitry. Furthermore, both photodiode and support circuitry are fabricated in the silicon material and must both be physically located within each pixel's area. This co-location of pixel-level silicon photodiode and silicon circuitry can lead to performance degradation; particularly when the pixel size is small. The source of this performance degradation is caused by light incident on the photodiode element interfering with the charge storage function of the global shutter storage node. This degradation means that small pixel pitch silicon (Si)-detectors with a global shutter are not generally practical without resorting to multi-wafer stacking approaches that add cost and complexity.

As discussed in the background, there is an ongoing need for photodetector devices with improved material properties and performance-related parameters such as more efficient charge separation, greater charge carrier mobility, longer diffusion lengths, higher quantum efficiencies, and sensitivity tunable to a desired range of electromagnetic spectra. There is also a need for lower cost, more reliable and more facile methods for fabricating such photodetector devices, as well as improved integration of the sensing elements with the signal processing electronics, improved scalability for large-area arrays, and applicability to curved, flexible or foldable substrates. There is also a need for photodetector devices that exhibit a sensitivity spanning a broad spectral range, such as both visible and IR or UV, visible and IR, to enable simultaneous detection in these ranges by a single photodetector device.

Thus, embodiments of the present inventive concept provide a stacked device structure incorporating a CQD photodetector and an optical shield element/optical blocking layer. This enables the fabrication of global shutter readout detector arrays with small pixel pitch that do not suffer from the degradation observed with Si-detectors. In other words, the combination of CQD photodetectors and an optical interference blocking structure as discussed herein in the fabrication of small pixel pitch photosensor arrays incorporating a global shutter readout architecture provides improved performance as discussed further herein.

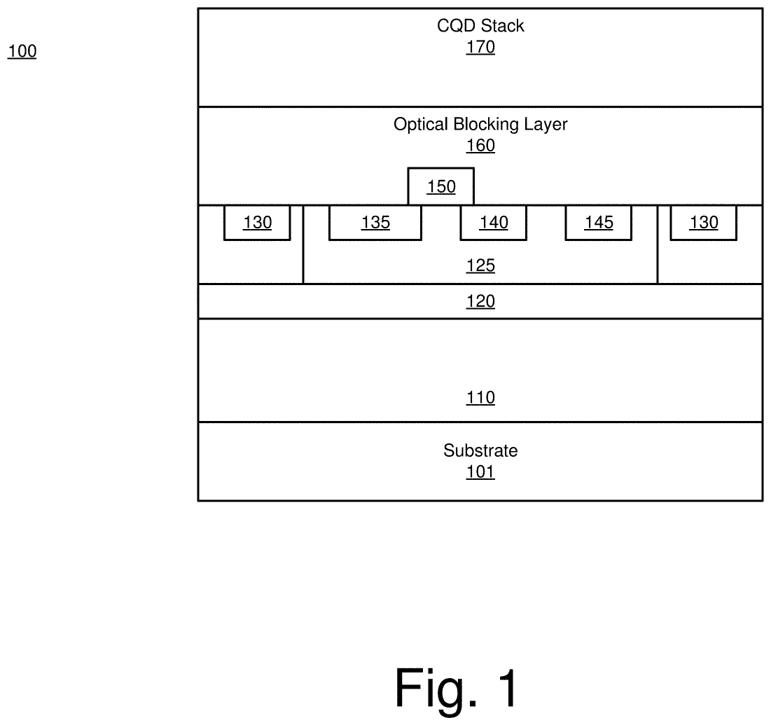

Referring now to FIG. 1, a cross-section of a CQD photodetector 100 including an optical blocking layer 160 in accordance with some embodiments of the present inventive concept will be discussed. Embodiments of the present inventive concept are described herein with reference to cross-section illustrations that are schematic illustrations of idealized embodiments of the present inventive concept. As such, variations from the shapes of the illustrations as a result, for example, of manufacturing techniques and/or tolerances, are to be expected. Thus, embodiments of the present inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present inventive concept.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Furthermore, although various layers, sections and regions of the photodetector may be discussed as being p-type and/or n-type, it is understood by those of skill in the art that in many devices these conductivity types may be switched without effecting the functionality of the device. If an element, region or layer is referred to as “n-type” this means that the element, layer or region has been doped to a certain concentration with n-type dopants, for example, Si, Germanium (Ge) or Oxygen. If an element region or layer is referred to “p-type” this means that the element, region or layer has been doped with p-type dopants, for example, magnesium (Mg), Beryllium (Be), Zinc (Zn), Calcium (Ca) or Carbon (C). In some embodiments, an element, region or layer may be discussed as “p⁺” or “n⁺,” which refers to a p-type or n-type element, region or layer having a higher doping concentration than the other p-type or n-type elements, regions or layers in the device. Finally, regions may be discussed as being epitaxial regions, implanted regions and the like. Although these regions may include the same material, the layer resulting from the various methods of formation may produce regions with different properties. In other words, an epitaxial grown region may have different properties than an implanted or deposited region of the same material.

Referring again to FIG. 1, as illustrated, the photodetector 100 includes a substrate 101 having the optical blocking layer/shield, for example, an optical blocking layer 160 formed thereon. The details of this structure will be discussed. However, it will be understood that the embodiments illustrated in FIG. 1 are provided for example only and, therefore, embodiments of the present inventive concept are not limited thereto. The substrate 101 may be any suitable substrate according to any known technology, such as bulk semiconductor technology. In some embodiments, the substrate 101 may be p-type. The doping concentration of the substrate 101 and the thickness thereof may change depending on the application. However, in some embodiments, the substrate 101 may be n-type, semi-insulating or not intentionally doped without departing from the scope of the present inventive concept.

An example structure of the device positioned between the substrate 101 and the optical blocking layer 160 will now be discussed. However, this structure is provided for example only and embodiments of the present inventive concept are not limited thereto. As further illustrated in FIG. 1, a p-type layer 110 is provided on the substrate 101 and may be an epitaxially grown p-type layer in some embodiments. An isolation layer 120 may be provided on the p-type layer 110. The isolation layer 120 may be a storage node isolation layer. Within a p-well 125, a storage node 135 may be provided in addition to both an n⁺ region 140 and a p⁺ region 145. A guard ring 130 (in cross section) may be provided to isolate an internal circuit region from the effects of moisture or ions. In some embodiments, the guard ring may reduce the likelihood of formation of cracks on an interlayer insulating layer of the internal circuit region during dicing, i.e., when a semiconductor wafer may be diced along a dicing region to divide the semiconductor wafer into a plurality of semiconductor devices, for example, semiconductor chips. One or more contacts 150 may be provided on the various regions 135, 140 and 145 as shown.

As discussed above, some embodiments of the present inventive concept provide a SWIR heterogenous material deposited photodetector comprising a deposited CQD film (CQD stack 170) (CQD photodetector element) over an optical blocking shield, for example, optical blocking layer 160, that enables a high shutter rejection ratio. The optical blocking layer 160 is provided directly on the device discussed above. In some embodiments, this device is made of silicon. In other words, the optical blocking layer 160 is provided directly on the die, having very small die sizes. Thus, these circuits can be used in relatively small devices including, for example, portable electronic devices. As further illustrated, a CQD stack 170 is provided on the blocking layer 160.

The optical blocking layer 160 may include a metal material having a thickness from about 10 nm to about 3000 nm. In some embodiments the material may be, for example, Au, Ag, W, Cu, Ti, Cr, Ni, Ge, Ta, and alloys (combinations) of the proceeding materials.

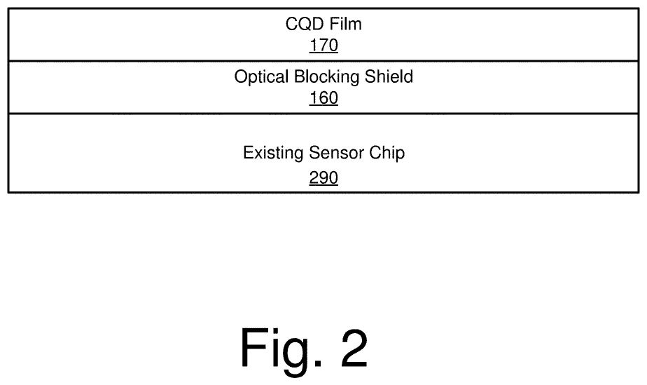

FIG. 2 is simple block diagram illustrating a cross section of a device including a CQD film 170 having an integrated optical blocking shield 160. As illustrated, the optical blocking shield 160 is provided directly on the existing sensor chip (integrated circuit) 290 between the sensor chip 290 and the CQD structure 170.

As discussed above, photodetectors including a CQD photodetector having an optical blocking layer/shield 160 therein may be used in a global shutter system. The addition of the blocking layer decreases the noise in a global shutter sensor by reducing the impact of parasitic stray light on the image data. This reduction in noise enables systems to be built with greater sensing precision owing to an improved signal to noise ratio (SNR). Thus, incorporating an optical shield (optical blocking layer 160) that is vertically integrated with the quantum-dot/optical-shield/Si-readout stack enables global-shutter operation without sacrificing performance experienced by the conventional systems discussed above.

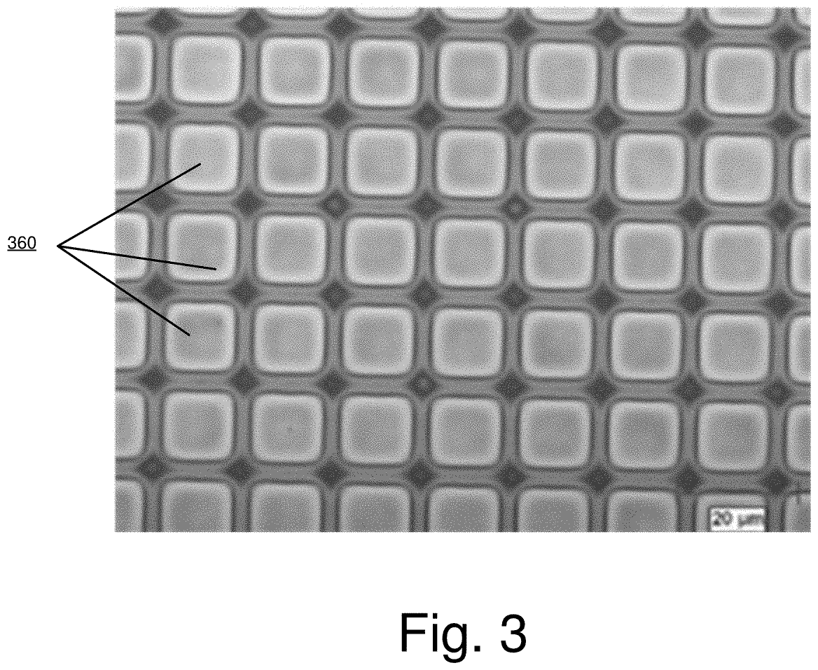

Referring now to FIGS. 3 through 6, the use of quantum dot based photodetectors as the light sensing element in a sensor array creates an opportunity for addressing the challenges faced by, for example, conventional silicon and other photosensor technologies in creating small pitch, global shutter sensor systems. This opportunity is provided by the ability to incorporate an optical blocking structure into, or underneath, the quantum dot photodetector structure.

The goal of an optical blocking structure is, generally, is to greatly reduce, or possibly eliminate, the ability of photons to enter into the region of the silicon circuitry that contains the amplifier, charge storage, and memory elements used to implement global shutter operation.

Referring now to FIG. 3, an optical microscope image of an array of optical blocking elements provided on the surface of an amplifier IC will be discussed. As illustrated, an array of optical blocking elements 360 is provided on the surface of an amplifier IC. Each element is formed on individual pixel circuitry. In embodiments illustrated in FIG. 3, the blocking element 360 is provided underneath the quantum dot photodetector. This optical blocking element is made from an optically opaque material, for example, a thin metal layer, which reduces the likelihood, or possibly prevents, stray photons from entering the silicon circuitry underneath the optical blocking layer and disrupting the functionality of the global shutter pixel design.

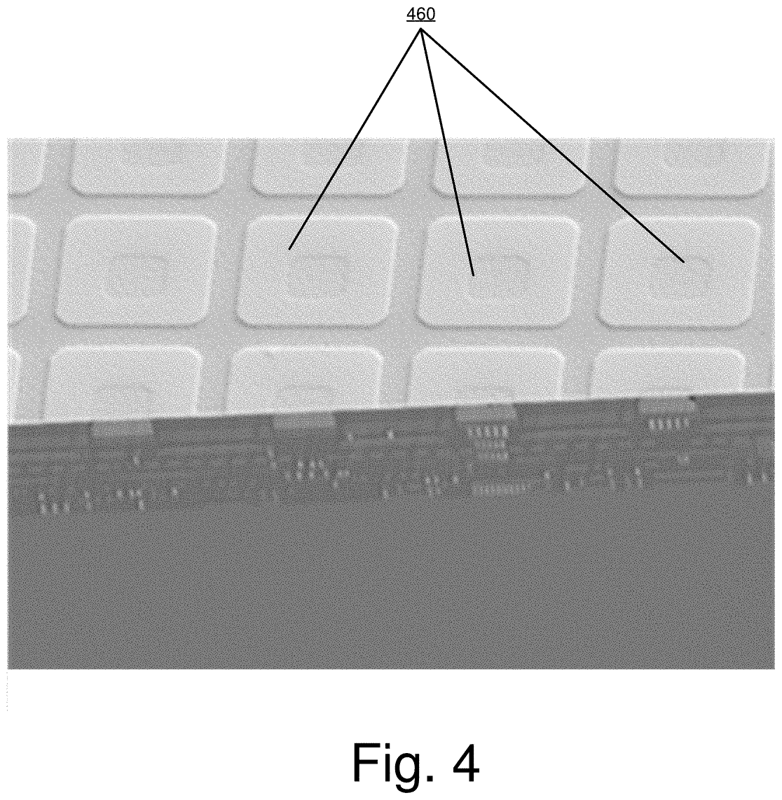

Referring now to FIG. 4, an image illustrating a portion of a device cross section and surface features will be discussed. As illustrated, square metal pads 460 are provided on the surface to provide an optical blocking structure. The features seen on the side of the die are part of the amplifier circuitry inside the amplifier IC.

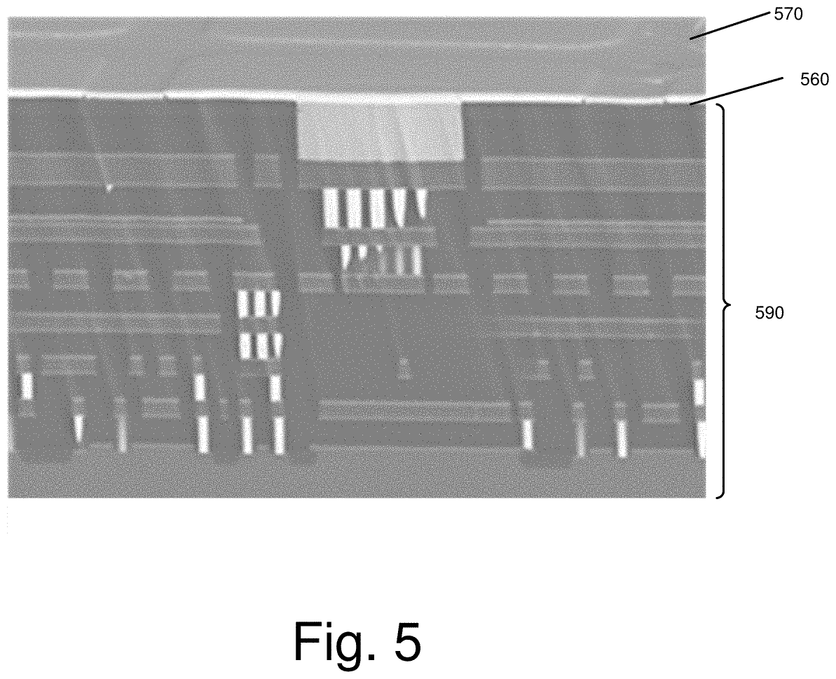

Referring now to FIG. 5, a cross-section image illustrating a photodetector global shutter pixel incorporating an optical blocking element 560 and a quantum dot photodiode 570 structure will be discussed. As illustrated, the pixel amplifier circuitry 590 is positioned underneath an optical blocking element 560 which is positioned underneath a thin film quantum dot photodiode structure 570.

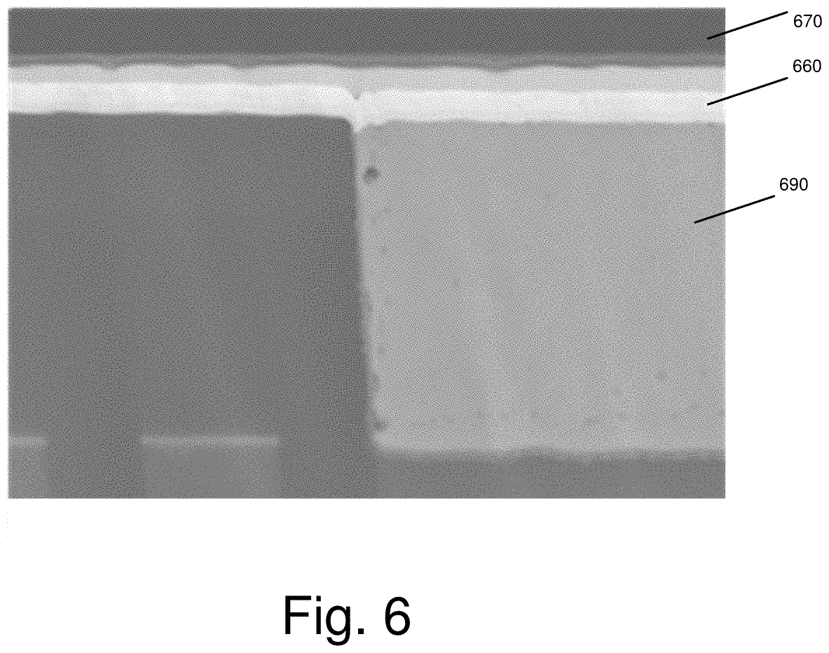

Finally, referring to FIG. 6, a cross section image of a photodetector pixel 670 on a metal optical blocking element 660 on an electrical contact formed in a silicon wafer is shown to provide a path 690 for photocurrent to be transferred into the amplifier IC.

In some embodiments, the optical blocking element may include materials that can consist of single or multiple layers of metal. The metal used can be selected for its combination of optical properties, such as skin depth and reflectivity at a given wavelength or range wavelengths. Metal material selections can also be determined by electrical and mechanical properties such as the metal's work function or adhesion properties. In some embodiments, optical blocker elements can also be formed using dielectric materials selected and deposited to form optical reflectors for a given wavelength, wavelengths or range of wavelengths. Other optical blocking materials may include, for example, narrow bandgap semiconductor materials with optical bandgaps smaller than the underlying silicon wafer.

Embodiments discussed herein include structures of global shutter sensor arrays that differ from conventional global shutter sensor arrays in a number of ways. For example, embodiments of the present inventive concept may be provided a single silicon wafer. Embodiments discussed herein utilizes quantum dot materials for the fabrication of the photodetector element. The structure discussed herein integrates the optical blocking element directly into the photodetector design. These differences provide important performance and cost advantages over other approaches to addressing the challenges discussed above with conventional devices.

In particular, embodiments of the present inventive concept are provided on a single wafer. Small pitch global shutter designs have in recent years been offered on the commercial market that are fabricated using traditional CMOS image sensor technologies. These image sensors are built using a back-side illuminated, stacked sensor design that incorporates two or more silicon wafers which are fabricated separately and then bonded together to form a photosensor array. The use of two or more different wafers is generally required to optically separate the photodetector element, for example, a silicon photodiode, from the amplifier circuitry by building the photodiode in one wafer and the amplifier array in another wafer. In contrast, embodiments of the present inventive concept, utilizes a single amplifier wafer. Use of a single wafer may reduce costs and may also significantly reduce the number of fabrication challenges inherent to the two-wafer bonding process that decrease yield and increase cost.

Some embodiments of the present inventive concept provide quantum dot photodetectors. Small pitch global shutter designs have traditionally been limited to CMOS sensor technologies. This means that the sensors could only be used for applications that require the detection of photons capable of being absorbed by silicon. This spans approximately the wavelengths from 200 nm to 1000 nm. Embodiments discussed herein, the sensor structure utilizes quantum dot materials, which can be selected to absorb photons from 200 nm to 5000 nm. This enables the use of infrared lasers and other infrared light sources in global shutter image systems. This is a particular advantage for applications that require eye-safe infrared lasers, or robust operation in high sunlight conditions, or operation in foggy or hazy conditions.

Further embodiments of the present inventive concept provide an integrated optical blocking element. As discussed above, some embodiments of the inventive concept incorporate an optical blocking element directly into the structure of the photodetector. This is an advantage over conventional devices because the performance of the photodetector is not compromised by the inclusion of the optical blocker. Other, previously demonstrated examples of the use of optical blockers in global shutter sensor systems achieved optical isolation between the photodiode and the amplifier/memory circuitry by inserting an isolating structure into the pixel area. This isolating structure required space that would otherwise be used by the photodiode element, and hence required a reduction in the photon collection efficiency. This introduced an unacceptable tradeoff between optical isolation and photon collection efficiency. In embodiments of the present inventive concept, there is no tradeoff between photon collection efficiency and optical blocking efficiency. A quantum dot photodiode fabricated with an optical blocker has the same photon collection efficiency as one fabricated without an optical blocker.

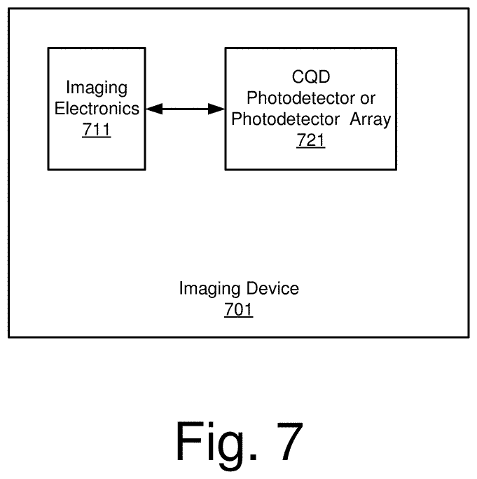

Referring now to FIG. 7, a block diagram of an example system including a CQD photodetector in accordance with some embodiments of the present inventive concept. As illustrated therein, the system includes an imaging device 701, a CQD photodetector or photodetector array 721 and associated imaging electronics 711. The imaging device 701 may be any image device or system that may use a CQD photodetector or array 721 as discussed herein. For example, the device 701 may be a high resolution application including, for example, a digital camera. As further discussed above, the CQD photodetector 721 having the integrated optical blocking shield as discussed herein may be used in a global shutter. The addition of the integrated optical blocking shield may provide a higher SRR, which may in turn provide an improved global shutter. It will be understood that FIG. 7 is provided as an example only and, therefore, the CQD photodetector having an integrated optical blocking shield as discussed herein may be used in any system suited therefore.

In the drawings and specification, there have been disclosed exemplary embodiments of the inventive concept. However, many variations and modifications can be made to these embodiments without substantially departing from the principles of the present inventive concept. Accordingly, although specific terms are used, they are used in a generic and descriptive sense only and not for purposes of limitation, the scope of the inventive concept being defined by the following claims.

What is claimed is:

1. A colloidal quantum dot (CQD) photodetector comprising:
an optical blocking shield; and
a CQD photodetector element on the optical blocking shield,
wherein the optical blocking shield is integrated with the CQD photodetector element to provide an integrated structure and the integrated structure is provided on a wafer; and
wherein the CQD photodetector detects light with sensitivity from about 250 nm to about 5000 nm.

2. The CQD photodetector of claim 1, wherein the optical blocking shield comprises an optically opaque material.

3. The CQD photodetector of claim 2, wherein the optically opaque material comprises one or more layers of a metal material.

4. The CQD photodetector of claim 3, wherein the optical blocking shield has a thickness of from about 10 nm to about 3000 nm and wherein the metal material includes one or more of Au, Ag, W, Cu, Ti, Cr, Ni, Ge and Ta.

5. The CQD photodetector of claim 1, wherein the optical blocking shield comprises a dielectric material.

6. The CQD photodetector of claim 1, wherein presence of the optical blocking shield substantially prevents stray photons from entering silicon circuitry in the wafer under the optical blocking shield.

7. The CQD photodetector of claim 1, wherein the wafer comprises a silicon wafer and wherein the CQD photodetector is positioned directly on a surface of the silicon wafer.

8. The CQD photodetector of claim 1, wherein the CQD photodetector is positioned in a high resolution light sensing application.

9. The CQD of claim 1, wherein the CQD photodetector is positioned in multispectral device that produces images from one or more of incident ultraviolet (UV) electromagnetic radiation, visible electromagnetic radiation and/or infrared electromagnetic radiation.

10. The CQD of claim 1, wherein the CQD photodetector is part of a global shutter in an imaging device.

11. The CQD photodetector of claim 1, wherein the wafer is a single wafer.

12. The CQD photodetector of claim 11, wherein the single wafer comprises circuitry for an amplifier.

13. The CQD photodetector of claim 1, wherein the CQD photodetector is used in multi-pixel light sensing arrays.

14. A global shutter for use with an imaging device, the global shutter including a colloidal quantum dot (CQD) photodetector, the CQD photodetector comprising:
an optical blocking shield; and
a CQD photodetector element on the optical blocking shield,
wherein the optical blocking shield is integrated with the CQD photodetector element to provide an integrated structure and the integrated structure is provided on a wafer; and
wherein the CQD photodetector detects light with sensitivity from about 250 nm to about 5000 nm.

15. The global shutter of claim 14, wherein the global shutter has an improved shutter rejection ratio (SRR) relative to conventional global shutters.

16. The global shutter of claim 14, wherein the global shutter comprises a global shutter sensing array provided on a single wafer.

17. The global shutter of claim 14, wherein presence of the optical blocking shield in the CQD photodetector prevent photons from entering a region of the wafer including silicon circuitry that contains an amplifier, charge storage, and memory elements used to implement global shutter operation.

18. The global shutter of claim 14, wherein presence of the optical blocking shield decreases noise in a global shutter sensor by reducing impact of parasitic stray light on associated image data.

19. The global shutter of claim 14, wherein the imaging device comprises a high resolution light sensing application.

20. The global shutter of claim 14:
wherein the optical blocking shield comprises one or more layers of at least one of an optically opaque material, a metal material and a dielectric material; and
wherein the optical blocking shield has a thickness of from about 10 nm to about 3000 nm.
